(19) United States
(12) Patent Application Publication
(10) Pub. No.: US 2023/0416909 A1
(43) Pub. Date: Dec. 28, 2023

(54) METHOD FOR FORMATION OF CONFORMAL ALD SIO2 FILMS

(71) Applicant: Applied Materials, Inc., Santa Clara, CA (US)

(72) Inventors: Geetika BAJAJ, Mumbai (IN); Seshadri GANGULI, Sunnyvale, CA (US); Gopi Chandran RAMACHANDRAN, Mumbai (IN); Srinivas GANDIKOTA, Santa Clara, CA (US)

(21) Appl. No.: 18/336,157

(22) Filed: Jun. 16, 2023

Related U.S. Application Data
(60) Provisional application No. 63/367,090, filed on Jun. 27, 2022.

(51) Int. Cl. C23C 16/40; C23C 16/04

(52) U.S. Cl. CPC C23C 16/402; C23C 16/045

(57) ABSTRACT

Embodiments of the disclosure provide a method of forming a dielectric film in trenches of a substrate. The utilization of the ALD process and introduction of an inhibitor material onto features defining the trenches and into the trenches provides for suppression of forming the dielectric film near the top surface of the features in the trenches. The dielectric film is formed via an ALD process. The ALD process includes sequentially exposing the substrate to an inhibitor material, a first precursor, a purge gas, an oxygen-containing precursor, and the purge gas during an ALD cycle, and repeating the ALD cycle to deposit the dielectric film.

### CROSS-REFERENCE TO RELATED APPLICATIONS

This application claims benefit of U.S. provisional patent application Ser. No. 63/367,090, filed Jun. 27, 2022, which is herein incorporated by reference.

### BACKGROUND

### Field

Embodiments of the present disclosure generally relate to vapor deposition processes, more specifically, to methods for forming dielectric films with an inhibitor material.

### Description of the Related Art

The fabrication of microelectronics or integrated circuit devices typically involves a complicated process sequence requiring hundreds of individual operations performed on semiconductors, dielectric and conductive substrates. Examples of these process operations include oxidation, diffusion, ion implantation, thin film deposition, cleaning, etching and lithography. Plasma processes are often used for thin film deposition and etching, which are performed in a plasma chamber.

Atomic layer deposition (ALD) is based upon atomic layer epitaxy (ALE) and employs chemisorption techniques to deliver precursor molecules on a substrate surface in sequential cycles. The cycle exposes the substrate surface to a first precursor and then to a second precursor. The first and second precursors react to form a product compound as a film on the substrate surface. The cycle is repeated to form the layer to a predetermined thickness. However, conformal growth of the film within features, such as a trench, is challenging. Thus, there is a need for improved film deposition methods.

### SUMMARY

In one embodiment, a method of forming a dielectric film within a processing chamber is provided. The method includes filling one or more trenches of a substrate during an atomic layer deposition (ALD) process with the dielectric film. The ALD process includes sequentially exposing the substrate to an inhibitor material, a first precursor, a purge gas in a first purge, an oxygen-containing precursor, and the purge gas in a second purge during an ALD cycle. The inhibitor material suppresses growth of the dielectric film. The method further includes repeating the ALD cycle to fill the trenches with the dielectric film until the dielectric film is at a predetermined thickness.

In another embodiment, a method of forming a dielectric film is provided. The method includes positioning a substrate in a processing chamber having an interior volume. The substrate includes adjacent features defining a plurality of trenches. The method includes introducing an inhibitor material on the substrate. A density of the inhibitor material decreases in the trenches from a top surface of the features to a bottom surface of the trenches. The method includes introducing a first precursor into the interior volume. The method includes introducing an oxygen-containing precursor into the interior volume. A dielectric film is formed when the first precursor and the oxygen-containing precursor interact. The method further includes filling the trenches with the dielectric film, wherein a rate of growth of the dielectric film on the substrate decreases as the density of the inhibitor material increases.

In yet another embodiment, a method of forming a dielectric film is provided. The method includes positioning a substrate in a processing chamber having an interior volume. The substrate includes adjacent features defining a plurality of trenches. The method includes introducing an inhibitor material on the substrate. A density of the inhibitor material decreases in the trenches from a top surface of the features to a bottom surface of the trenches. The method includes introducing a first precursor into the interior volume. The method includes introducing an oxygen-containing precursor into the interior volume. A dielectric film is formed when the first precursor and the oxygen-containing precursor interact. The method includes repeating the introducing of the inhibitor material, the first precursor, and the oxygen-containing precursor until the dielectric film reaches a predetermined thickness. The method includes filling the trenches with the dielectric film. A rate of growth of the dielectric film on the substrate decreases as the density of the inhibitor material increases.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a cross-sectional view of a processing chamber suitable for performing a deposition process to deposit or otherwise form a dielectric film, according to embodiments described herein.

FIG. 2 is a flow diagram illustrating operations of the method of forming a dielectric film, as shown in FIGS. 3A-3D, according to embodiments described herein.

FIGS. 3A-3D are schematic, cross-sectional views of a trench in a substrate during a method of forming a dielectric film, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure provide methods for depositing dielectric films into trenches of a substrate. The methods include the use of an inhibitor material to achieve a more conformal deposition within the trenches during an atomic layer deposition (ALD) process. For example, during a plasma enhanced ALD process. Specifically, surfaces of the substrate with relatively high aspect ratio features are easily and more conformally coated with the dielectric film by ALD over other traditional deposition processes. The film may contain one or multiple layers or films of the same of varying composition.

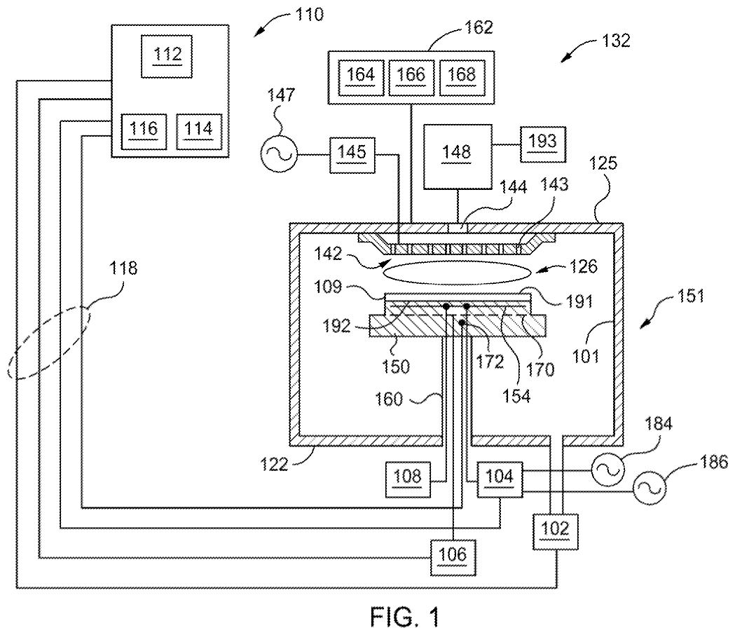

FIG. 1 is a cross-sectional view of a processing chamber 132 suitable for performing a deposition process to deposit or otherwise form a dielectric film, according to one or more embodiments described and discussed herein. The processing chamber 132 can perform thermal and/or plasma processes.

The processing chamber 132 includes a chamber body 151. The chamber body 151 includes a chamber lid 125, a sidewall 101 and a bottom wall 122 that define an interior volume 126. A substrate support pedestal 150 is provided in the interior volume 126 of the chamber body 151. The pedestal 150 may be fabricated from aluminum, ceramic, aluminum nitride, and other suitable materials. The pedestal 150 may be moved in a vertical direction inside the chamber body 151 using a lift mechanism (not shown).

The pedestal 150 may include an embedded heater element 170 suitable for controlling the temperature of a substrate 109 supported on the pedestal 150. In one or more embodiments, the pedestal 150 may be resistively heated by applying an electric current from a power supply 106 to the heater element 170. The electric current supplied from the power supply 106 is regulated by a controller 110 to control the heat generated by the heater element 170, thus maintaining the substrate 109 and the pedestal 150 at a substantially constant temperature during film deposition at any suitable temperature range. In some embodiments, the pedestal 150 may also include a chiller (not shown) as needed to cool the pedestal 150 at a range lower than room temperature as needed. A temperature sensor 172, such as a thermocouple, may be embedded in the substrate support pedestal 150 to monitor the temperature of the pedestal 150 in a conventional manner. The measured temperature is used by the controller 110 to control the power supplied to the heater element 170 to maintain the substrate at a desired temperature.

The pedestal 150 generally includes a plurality of lift pins (not shown) disposed therethrough that are configured to lift the substrate 109 from the pedestal 150 and facilitate exchange of the substrate 109 with a robot (not shown).

The pedestal 150 contains at least one electrode for retaining the substrate 109 on the pedestal 150. The electrode 192 is driven by a chucking power source 108 to develop an electrostatic force that holds the substrate 109 to the pedestal surface. Alternatively, the substrate 109 may be retained to the pedestal 150 by clamping, vacuum or gravity.

In one or more embodiments, which can be combined with other embodiments described herein, the pedestal 150 is configured as a cathode having the electrode 192 embedded therein coupled to at least one RF bias power source, shown in FIG. 1 as two RF bias power sources 184, 186. Although the example depicted in FIG. 1 shows two RF bias power sources, 184, 186, it is noted that the number of the RF bias power sources may be any number as needed. The RF bias power sources 184, 186 are coupled between the electrode 192 disposed in the pedestal 150 and another electrode, such as a gas distribution plate 142 or chamber lid 125 of the processing chamber 132. The RF bias power source 184, 186 excites and sustains a plasma discharge formed from the gases disposed in the processing region of the processing chamber 132.

In the embodiment depicted in FIG. 1, the dual RF bias power sources 184, 186 are coupled to the electrode 192 disposed in the pedestal 150 through a matching circuit 104. The signal generated by the RF bias power source 184, 186 is delivered through matching circuit 104 to the pedestal 150 through a single feed to ionize the gas mixture provided in the processing chamber 132, thereby providing ion energy necessary for performing a deposition or other plasma enhanced process. The RF bias power sources 184, 186 are generally capable of producing an RF signal having a frequency of from about 50 kHz to about 200 MHz and a power of 0 watts to about 5,000 watts.

A vacuum pump 102 is coupled to a port formed in the bottom wall 122 of the chamber body 151. The vacuum pump 102 is used to maintain a desired gas pressure in the chamber body 151. The vacuum pump 102 also evacuates post-processing gases and by-products of the process from the chamber body 151.

The processing chamber 132 includes one or more gas delivery passages 144 coupled through the chamber lid 125 of the processing chamber 132. The gas delivery passages 144 and the vacuum pump 102 are positioned at opposite ends of the processing chamber 132 to induce laminar flow within the interior volume 126 to minimize particulate contamination.

The gas delivery passage 144 is coupled to the gas panel 193 through a remote plasma source (RPS) 148 to provide a gas mixture into the interior volume 126. In one or more embodiments, the gas mixture supplied through the gas delivery passage 144 may be further delivered through a gas distribution plate 142 disposed below the gas delivery passage 144. In one example, the gas distribution plate 142 having a plurality of apertures 143 is coupled to the chamber lid 125 of the chamber body 151 above the pedestal 150. The apertures 143 of the gas distribution plate 142 are utilized to introduce process gases from the gas panel 193 into the chamber body 151. The apertures 143 may have different sizes, number, distributions, shape, design, and diameters to facilitate the flow of the various process gases for different process requirements. A plasma may be formed from the process gas mixture exiting the gas distribution plate 142 to enhance thermal decomposition of the process gases resulting in the deposition of the dielectric film on a surface 191 of the substrate 109.

The gas distribution plate 142 and substrate support pedestal 150 may be formed as a pair of spaced apart electrodes in the interior volume 126. One or more RF sources 147 provide a bias potential through a matching network 145 to the gas distribution plate 142 to facilitate generation of a plasma between the gas distribution plate 142 and the pedestal 150. Alternatively, the RF sources 147 and matching network 145 may be coupled to the gas distribution plate 142, substrate support pedestal 150, or coupled to both the gas distribution plate 142 and the substrate support pedestal 150, or coupled to an antenna (not shown) disposed exterior to the chamber body 151. In one or more embodiments, the RF sources 147 may provide between about 10 watts and about 3,000 watts at a frequency of about 30 kHz to about 13.6 MHz. Alternatively, the RF source 147 may be a microwave generator that provide microwave power to the gas distribution plate 142 that assists generation of the plasma in the interior volume 126. Examples of gases that may be supplied from the gas panel 193 may include one or more fluorine-containing gases, one or more chlorine-containing gases, one or more oxygen-containing gases, one or more hydrogen-containing gases, a purge gas, a carrier gas, or any combination thereof.

In some embodiments, which can be combined with other embodiments described herein, the remote plasma source (RPS) 148 may be alternatively coupled to the gas delivery passages 144 to assist in forming a plasma from the gases supplied from the gas panel 193 into the in the interior volume 126. The remote plasma source 148 provides plasma formed from the gas mixture provided by the gas panel 193 to the processing chamber 132. In other embodiments, which can be combined with other embodiments described herein, the RPS 148 is removed.

In one or more embodiments, which can be combined with other embodiments described herein, the processing chamber 132 is configured to perform thermal ALD and/or PE-ALD processes. An ALD process system 162 is coupled to the processing chamber 132. The ALD process system 162 can include one, two, three, or more sources 164, 166, and 168 fluidly coupled to the chamber lid 125 and/or the chamber body 151. The sources 164, 166, and 168 include chemical precursors, carrier gas, inhibitor material, purge gas, and/or other sources of compounds and/or gases used in the ALD process. In one or more examples, the source 164 contains one or more precursor gases, the source 166 contains one or more inhibitor materials, and the source 168 contains one or more purge or carrier gases. Although not shown, the ALD process system 162 can also include valves, conduits, controllers, computer system, and other components utilized to perform ALD processes. Each of the sources 164, 166, and 168 is independently in fluid communication with the gas distribution plate 142 via the chamber lid 125 and/or the chamber body 151. For example, as depicted in FIG. 1, the sources 164, 166, and 168 pass through the chamber lid 125 and are independently in fluid communication with the gas distribution plate 142.

The controller 110 includes a central processing unit (CPU) 112, a memory 116, and a support circuit 114 utilized to control the process sequence and regulate the gas flows from the gas panel 193. The CPU 112 may be of any form of a general purpose computer processor that may be used in an industrial setting. The software routines can be stored in the memory 116, such as random access memory, read only memory, floppy, or hard disk drive, or other form of digital storage. The support circuit 114 is coupled to the CPU 112 and may include cache, clock circuits, input/output systems, power supplies, and the like. Bi-directional communications between the controller 110 and the various components of the processing chamber 132 are handled through numerous signal cables collectively referred to as signal buses 118, some of which are illustrated in FIG. 1. In one or more embodiments, the controller 110 is used to operate the RPS 148 and/or the ALD process system 162.

Accordingly, the ALD process described below enables the formation of high quality, conformal films formed on the substrate 109 disposed in the processing chamber 132. A variety of plasma deposition and etch chambers may benefit from the teachings disclosed herein. It is contemplated that other suitable plasma reactors, including those from other process types, may be adapted to benefit from the disclosure.

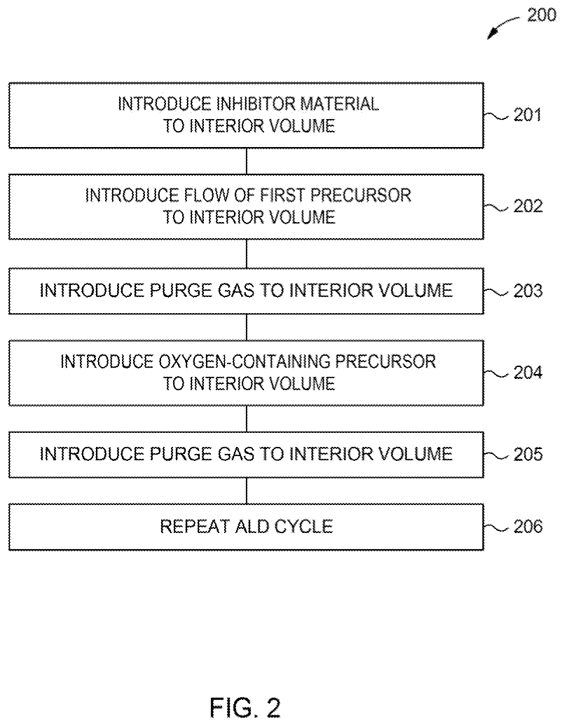

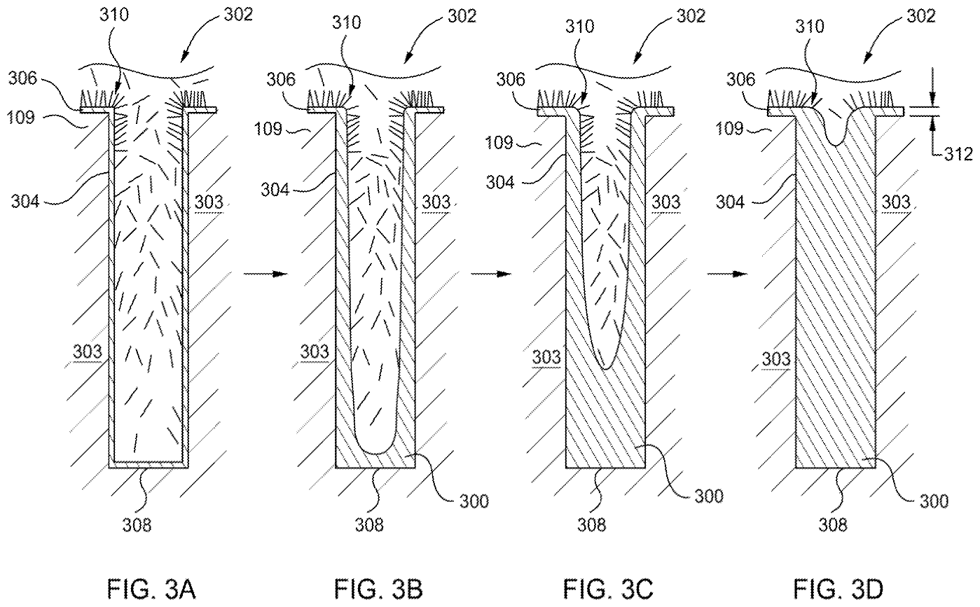

FIG. 2 is a flow diagram illustrating operations of the method 200 of forming a dielectric film 300, as shown in FIGS. 3A-3D. To facilitate explanation, the method 200 will be described with reference to FIG. 1 and FIGS. 3A-3D. FIGS. 3A-3D are schematic, cross-sectional views of a trench 302 in a substrate 109 during a method of forming a dielectric film 300. However, it is to be noted that an ALD chamber other than processing chamber 132 of FIG. 1 may be utilized in conjunction with the method 200. The method 200 includes forming a dielectric film 300 via an ALD process on the substrate 109 and conformally filling the trenches 302 with the dielectric film 300, as shown in FIGS. 3A-3D. The ALD process described herein may be one of a thermal ALD process or a plasma enhanced ALD process.

The substrate 109 is formed of semiconducting material, such as silicon, polysilicon, or silicon-germanium, and includes a plurality of trenches 302 formed therein. The plurality of trenches 302 may be utilized to define a plurality of spaced apart and electrically isolated active areas 303. The plurality of trenches 302 are further defined by adjacent features 304 of the substrate 109. The adjacent features 304 correspond to the active areas 303. The features 304 may have a high aspect ratios, such as aspect ratios of about 10:1 or greater, 20:1 or greater, or 30:1 or greater. The trenches 302 are to be filled with a dielectric film 300, such as silicon oxide, and are used to electrically isolate the active areas 303 from one another and thus prevent current leakage therebetween.

Prior to the method 200, the substrate 109 is positioned in the processing chamber 132 on the pedestal 150. In one embodiment, which can be combined with other embodiments described herein, the substrate 109 is hydroxylated (e.g., the substrate 109 is covered with hydroxyl (—OH) groups). In other embodiments, which can be combined with other embodiments described herein, hydroxyl (—OH) groups are native oxides of the substrate 109.

The substrate 109 is heated to a temperature of about 30° C. to about 500° C., about 50° C. to about 500° C., about 80° C. to about 500° C., about 100° C. to about 500° C., about 200° C. to about 500° C., about 250° C. to about 500° C., about 300° C. to about 500° C., about 350° C. to about 500° C., about 400° C. to about 500° C., or greater during the method 200. For example, the temperature of the substrate 109 is maintained between about 220° C. and about 230° C.

As described in detail below, the method 200 can include multiple cycles of an ALD cycle. The ALD cycle, as described below, is defined as a pulse of inhibitor material 310, a pulse of a precursor material, a purge operation, a pulse of an oxygen-containing precursor, and a purge operation. The ALD cycle may be repeated as necessary to form the dielectric film 300. The ALD process includes transferring the substrate 109 into the processing chamber 132 and positioning the substrate 109 on the pedestal 150.

At operation 201, a pulse of inhibitor material 310 is introduced to the interior volume 126 utilizing an ALD process. The inhibitor material 310 is deposited on the substrate 109 from the gas distribution plate 142. Specifically, the inhibitor material 310 is provided from one of the sources 164, 166, and 168 to the interior volume 126. The inhibitor material 310, due to the deposition from the gas distribution plate 142, will be deposited onto a top surface 306 of the features 304 and into the trenches 302. A density of the inhibitor material 310 decreases in the trenches 302 from the top surface 306 of the features 304 to a bottom surface 308 of the trenches 302. In other words, the density of the inhibitor material 310 decreases in the trenches 302 as depth into the trench 302 increases. The inhibitor material 310 can bind to hydroxylated sites on the substrate 109 to suppress film nucleation during later operations of the ALD cycle. The inhibitor material 310 lowers a sticking coefficient of the precursor gases introduced during the ALD cycle.

The inhibitor material 310 is pulsed for between about 2 seconds (s) and about 20 s. For example, the substrate 109 is exposed to the inhibitor material 310 for between about 10 s and about 40 s. The inhibitor material 310 is flowed in at a flow rate between about 5 sccm and about 100 sccm. The pressure in the chamber body 151 is greater than about 5 torr. The flow rate of the inhibitor will depend on the chamber pressure to create the pre-determined concentration of the inhibitor material 310. The inhibitor material 310 is an amine containing chemical which can be a primary amine, a secondary amine, or a tertiary amine. The inhibitor material can also be an aromatic amine having a nitrogen atom connected to an aromatic ring and another amine containing compound. Further, a nitrogen containing plasma can be used as the inhibitor material. Alternatively, the inhibitor material 310 includes organic aminosilane molecules such as (3-Aminopropyl)trimethoxysilane. In one example, the inhibitor material 310 is an ammonia (NH₃) containing plasma, or a plasma generated from ammonia. In another example, the inhibitor material is one of R—NH₂, R—N₃, R—CₓN_{y} (where x and y are integers), heteroaromatics, R—NO₂, and R—NO.

At operation 202, a flow of a first precursor is introduced to the interior volume 126. The first precursor is provided to the interior volume 126. The first precursor flows to the substrate 109. The first precursor may be provided from one of the sources 164, 166, and 168 to the interior volume 126.

In some examples, during each ALD cycle, the substrate 109 is exposed to the first precursor for about 0.1 seconds to about 10 seconds to deposit a layer of the first precursor. In other examples, during each ALD cycle, the substrate 109 is exposed to the first precursor for about 0.5 seconds to about 3 seconds. For example, the substrate 109 is exposed to the first precursor for about 500 ms. In one example, the first precursor is a silicon containing precursor. For example, the first precursor includes tetrasubsitituted aminosilanes such as tetrakis(dimethylamino)silane, trisubsitituted aminosilanes such as tris(dimethylamino)silane and/or tris(diethylamino)silane, disubsitituted aminosilanes such as bis(dimethylamino)silane, bis(diethylamino)silane, and/or bis(tertbutylamino)silane, and monosubsitituted aminosilanes such as di-isopropylaminosilane, and/or di(sec-butylamino)silane. In another example, the first precursor is an aminodisilane precursor such as 1,2-Bis(diisopropylamino)disilane (BDIPADS). The flow rate of the first precursor is between about 0.5 slm and about 10 slm.

At operation 203, a purge gas is introduced into the interior volume 126. The purge gas flows through the interior volume 126 to the vacuum pump 102 in order to purge the first precursor from the processing chamber 132. The inhibitor material 310 remains on the substrate 109. The purge gas may be provided from one of the sources 164, 166, and 168 to the interior volume 126. The flow rate of the purge gas is between about 0.5 slm and about 10 slm.

In some examples, during each ALD cycle, the substrate 109 is exposed to the purge gas for about 0.5 seconds to about 30 seconds. In other examples, during each ALD cycle, the substrate 109 is exposed to the purge gas for about 1 second to about 10 seconds. The purge gas includes one or more of nitrogen (N₂), argon, helium, hydrogen (H₂), oxygen (O₂), or any combination thereof.

At operation 204, a flow of an oxygen-containing precursor is introduced to the interior volume 126. The oxygen-containing precursor is a second precursor. The oxygen-containing precursor is provided to the interior volume 126. The oxygen-containing precursor flows to the substrate 109. The oxidant may be provided from one of the sources 164, 166, and 168 to the interior volume 126.

The oxygen-containing precursor reacts with the layer of the first precursor on the substrate 109, forming a dielectric film 300 on the substrate 109. The dielectric film 300 is also formed in the trenches 302 and on the features 304. As a distance from the top surface 306 of the features 304 increased into the trenches 302, a concentration of molecules of the precursors decreases, leading to non-conformal growth of the dielectric film 300. The inhibitor material 310, which has a higher density near the top surface 306, will suppress growth of the dielectric film 300 by absorbing the material of the dielectric film 300 before the dielectric film 300 forms in the trenches 302. The inhibitor material 310 allows the first precursor and the oxygen-containing precursor to survive deeper into the trench 302 before reacting to form the dielectric film 300. Increasing the density of the inhibitor material 310 increases the density of absorbed dielectric film by the inhibitor material 310.

Increasing the concentration of inhibitor material 310 correlates to suppressed growth of the dielectric film 300. The inhibitor material 310 utilizes deactivation of the active areas 303 to suppress the growth of the dielectric film by allowing for more precursor gas to be available at the bottom of the trench 302. Suppressing the growth of the dielectric film 300 leads to a more conformal film formation in the trenches 302 and improves the quality of the dielectric material fill in the trenches 302. Typically growth of the dielectric film 300 consumes precursor molecules and the partial pressure of the precursor molecules falls near the bottom surface 308 of the trench 302. Thus, the method 200 will allow for a consistent formation of the dielectric film 300.

The material of the dielectric film 300 is determined based on the material of the first precursor and the oxygen-containing precursor. For example, the dielectric film 300 can be a metal oxide. In another example, the dielectric film 300 is a silicon oxide (SiO₂) material. For example, the first precursor includes BDIPADS and the oxygen-containing precursor is ozone or oxygen plasma to form a silicon oxide dielectric film 300.

During each cycle of a thermal ALD cycle, the growth per ALD cycle (GPC) of the dielectric film 300 is between about 0.95 angstroms per cycle and about 1.4 angstroms per cycle. Utilizing the inhibitor material 310 leads to a decrease in GPC of between about 10% and about 60%. During each cycle of a plasma enhanced ALD cycle, the growth per ALD cycle (GPC) of the dielectric film 300 is between about 0.5 angstroms per cycle and about 3.0 angstroms per cycle. Utilizing the inhibitor material 310 leads to a decrease in GPC of between about 10% and about 60%. As such, the decrease in GPC allows for more conformal growth of the dielectric film 300 throughout the trench 302. Conformal growth of the dielectric film 300 allows to maintain the shape of the layers and materials disposed below the dielectric film 300. For example, the shape of a gate dielectric of a 3D transistor is maintained.

In some examples, during each ALD cycle, the substrate 109 is exposed to the oxygen-containing precursor for about 0.1 seconds to about 10 seconds. In other examples, during each ALD cycle, the substrate 109 is exposed to the oxygen-containing precursor for about 0.5 seconds to about 4 seconds. For example, the substrate 109 is exposed to the oxygen-containing precursor for about 4 s. The flow rate of the oxygen-containing precursor is between about 0.5 slm and about 10 slm. In embodiments where a thermal ALD process is utilized, water vapor or ozone may be used as the oxygen-containing precursor. In embodiments where a plasma enhanced ALD process is utilized, an oxygen plasma is used as the oxygen-containing precursor.

The oxygen-containing precursor can be or include one or more of water, oxygen (O₂), an O₃—H₂O mixture, atomic oxygen, ozone, nitrous oxide, alcohols, one or more peroxides (e.g., hydrogen peroxide and/or an organic peroxide), oxygen containing plasmas thereof, or any combination thereof. The oxygen-containing plasma may be formed by flowing the oxygen-containing precursor across the interior volume 126 and activating the oxygen-containing precursor into the oxygen-containing plasma. The oxygen-containing plasma may be formed in a remote plasma source that provides radicals of the oxygen-containing plasma to the interior volume 126.

At operation 205, a purge gas is introduced into the interior volume 126. The purge gas flows through the interior volume 126 to the vacuum pump 102 in order to purge the first precursor and the oxygen-containing precursor from the processing chamber 132. The purge gas may be provided from one of the sources 164, 166, and 168 to the interior volume 126.

At operation 206, the ALD cycle is repeated. Operations 201-205 are repeated as needed to form the dielectric film 300. In one or more embodiments, which can be combined with other embodiments described herein, the ALD cycle can be repeated until the dielectric film 300 has a predetermined thickness 312 on the top surface 306 of the features 304. Due to the inhibitor material 310, the dielectric film 300 grows conformally in the trench 302 at a slower GPC to allow for improved quality of the dielectric material fill in the trenches 302. In some embodiments, different precursors, such as a second precursor, having a different material than the first precursor, may be introduced during subsequent ALD cycles. It is contemplated that the inhibitor material 310 may not be added in every ALD cycle but only when required to achieve a conformal filing of the trenches 302.

As shown in FIGS. 3A-3D, as more ALD cycles are completed, the dielectric film 300 fills the trench 302 conformally. The dielectric film 300 has a thickness 312 of about 0.5 nm to about 200 nm, about 1 nm to about 150 nm, about 2 nm to about 100 nm, about 5 to about 80 nm, about 8 nm to about 60 nm, about 10 nm to about 50 nm, about 12 nm to about 35 nm, about 15 nm to about 30 nm, or greater. For example, the pre-determined thickness 312 is between about 1 nm and about 10 μm.

Each ALD cycle is repeated from 2, 3, 4, 5, 6, 8, about 10, about 12, or about times to about 18, about 20, about 25, about 30, about 40, about 50, about 65, about about 100, about 120, about 150, about 200, about 250, about 300, about 350, about 400, about 500, about 800, about 1,000, or more times to form the dielectric film 300. For example, the ALD cycle is repeated for between about 50 cycles and about 75 cycles. The dielectric film 300 can contain multiple sublayers formed or otherwise deposited during the ALD process. A sublayer is formed or otherwise deposited by each cycle of the ALD process. The protective coating or the cerium oxide layer can include 2, 3, 4, 5, 6, 8, about 10, about 12, or about 15 sublayers to about 18, about 20, about 25, about 30, about 40, about 50, about 65, about 80, about 100, about 120, about 150, about 200, about 250, about 300, about 350, about 400, about 500, about 800, about 1,000, or more sublayers.

In summation, a method of forming a dielectric film in trenches of a substrate is provided. The utilization of the ALD process and introduction of an inhibitor material onto features defining the trenches and into the trenches provides for suppression of forming the dielectric film near the top surface of the features in the trenches. As such, the growth per cycle of the dielectric film is reduced to allow for conformal growth in the trenches, specifically near the bottom surface of the trench. Conformal growth of the film will allow for an improved process of filling the trenches with the dielectric film. Therefore, quality of semiconductors, dielectric and conductive substrates will improve.

While the foregoing is directed to examples of the present disclosure, other and further examples of the disclosure may be devised without departing from the basic scope thereof, and the scope thereof is determined by the claims that follow.

What is claimed is:

1. A method of forming a dielectric film within a processing chamber, comprising:
filling one or more trenches of a substrate during an atomic layer deposition (ALD) process with the dielectric film, wherein the ALD process comprises:
sequentially exposing the substrate to an inhibitor material, a first precursor, a purge gas in a first purge, an oxygen-containing precursor, and the purge gas in a second purge during an ALD cycle, wherein the inhibitor material suppresses growth of the dielectric film; and
repeating the ALD cycle to fill the trenches with the dielectric film until the dielectric film is at a predetermined thickness.

2. The method of claim 1, wherein the inhibitor material is one of a primary amine, a secondary amine, or a tertiary amine.

3. The method of claim 1, wherein the inhibitor material is an aromatic amine having a nitrogen atom connected to an aromatic ring and another amine containing compound.

4. The method of claim 1, wherein the inhibitor material is an ammonia (NH₃) containing plasma.

5. The method of claim 1, wherein the ALD cycle is a thermal ALD process.

6. The method of claim 1, wherein the substrate is exposed to the inhibitor material for between about 2 s and about 20 s.

7. The method of claim 1, wherein the pre-determined thickness is between about 1 nm and about 10 μm.

8. The method of claim 1, wherein the dielectric film is a silicon oxide (SiO₂) material.

9. The method of claim 1, wherein:
the inhibitor material is a plasma comprising ammonia;
the first precursor is selected from the group consisting of 1,2-bis(diisopropylamino)disilane (BDIPADS), tetrakis(dimethylamino)silane, tris(dimethylamino)silane, tris(diethylamino)silane, bis(dimethylamino)silane, bis(diethylamino)silane, bis(tertbutylamino)silane, di-isopropylaminosilane, and di(sec-butylamino)silane;
the oxygen-containing precursor is ozone or oxygen-containing plasma; and
the dielectric film is a silicon oxide (SiO₂) material.

10. A method of forming a dielectric film, comprising:
positioning a substrate in a processing chamber having an interior volume, wherein the substrate includes adjacent features defining a plurality of trenches;
introducing an inhibitor material on the substrate, wherein a density of the inhibitor material decreases in the trenches from a top surface of the features to a bottom surface of the trenches;
introducing a first precursor into the interior volume;
introducing an oxygen-containing precursor into the interior volume, wherein a dielectric film is formed when the first precursor and the oxygen-containing precursor interact; and
filling the trenches with the dielectric film, wherein a rate of growth of the dielectric film on the substrate decreases as the density of the inhibitor material increases.

11. The method of claim 10, wherein the inhibitor material is one of a primary amine, a secondary amine, or a tertiary amine.

12. The method of claim 10, wherein the inhibitor material is an aromatic amine having a nitrogen atom connected to an aromatic ring and another amine containing compound.

13. The method of claim 10, wherein the inhibitor material is an ammonia (NH₃) containing plasma.

14. The method of claim 10, wherein the substrate is exposed to the inhibitor material for between about 10 s and about 30 s.

15. The method of claim 10, wherein the dielectric film is a silicon oxide material.

16. The method of claim 10, wherein:
the inhibitor material is an ammonia (NH₃) containing plasma; and
the dielectric film is a silicon oxide (SiO₂) material.

17. The method of claim 10, wherein:
the inhibitor material is an ammonia (NH₃) containing plasma;
the first precursor is selected from the group consisting of 1,2-bis(diisopropylamino)disilane (BDIPADS), tetrakis(dimethylamino)silane, tris(dimethylamino)silane, tris(diethylamino)silane, bis(dimethylamino)silane, bis(diethylamino)silane, bis(tertbutylamino)silane, di-isopropylaminosilane, and di(sec-butylamino)silane;
the oxygen-containing precursor is ozone or oxygen-containing plasma; and
the dielectric film is a silicon oxide (SiO₂) material.

18. A method of forming a dielectric film, comprising:
positioning a substrate in a processing chamber having an interior volume, wherein the substrate includes adjacent features defining a plurality of trenches;
introducing an inhibitor material on the substrate, wherein a density of the inhibitor material decreases in the trenches from a top surface of the features to a bottom surface of the trenches;
introducing a first precursor into the interior volume;
introducing an oxygen-containing precursor into the interior volume, wherein a dielectric film is formed when the first precursor and the oxygen-containing precursor interact;
repeating the introducing of the inhibitor material, the first precursor, and the oxygen-containing precursor until the dielectric film reaches a predetermined thickness;
and filling the trenches with the dielectric film, wherein a rate of growth of the dielectric film on the substrate decreases as the density of the inhibitor material increases.

19. The method of claim 18, wherein:
the inhibitor material is an ammonia (NH₃) containing plasma; and
the dielectric film is a silicon oxide (SiO₂) material.

20. The method of claim 18, wherein:
the inhibitor material is an ammonia (NH₃) containing plasma;
the first precursor is selected from the group consisting of 1,2-bis(diisopropylamino)disilane (BDIPADS), tetrakis(dimethylamino)silane, tris(dimethylamino)silane, tris(diethylamino)silane, bis(dimethylamino)silane, bis(diethylamino)silane, bis(tertbutylamino)silane, di-isopropylaminosilane, and di(sec-butylamino)silane;
the oxygen-containing precursor is ozone or oxygen-containing plasma; and
the dielectric film is a silicon oxide (SiO₂) material.
